(19) United States
(12) Patent Application Publication
(10) Pub. No.: US 2014/0353602 A1
(43) Pub. Date: Dec. 4, 2014

(54) DISPLAY PANEL AND A METHOD OF MANUFACTURING THE SAME

(71) Applicant: Samsung Display Co., LTD., Yongin-City (KR)

(72) Inventor: Chang-Wook KIM, Yongin-City (KR)

(73) Assignee: Samsung Display Co., LTD., Yongin-City (KR)

(21) Appl. No.: 14/046,075

(22) Filed: Oct. 4, 2013

(30) Foreign Application Priority Data
Jun. 4, 2013 (KR) 10-2013-0063874

(51) Int. Cl. H01L 27/32

(52) U.S. Cl. CPC H01L 27/3258
USPC 257/40; 438/46

(57) ABSTRACT

A display panel may include an organic light emitting diode, a first film disposed on the organic light emitting diode and a second film comprising a fluoro polymer and disposed on the first film.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

This application claims priority under 35 U.S.C. §119 to Korean Patent Application No. 10-2013-0063874, filed on Jun. 4, 2013 in the Korean Intellectual Property Office (KIPO), the contents of which are herein incorporated by reference in its entirety.

### BACKGROUND

1. Field

Example embodiments relate to a display panel and a method of manufacturing the same. More particularly, example embodiments relate to a display panel including a film having improved transparency and a method of manufacturing the same.

2. Description of the Related Technology

An image display device capable of displaying various information is important technology in the information and communication technology. The image display device has been developed to become thinner and lighter and to have portability and high performance. Recently, a flexible display capable of bending is being developed for spacing and convenience.

Intensity with respect to wavelength is important factor in flexible display quality evaluation. Recently, transparency of flexible display is also important factor in flexible display quality evaluation.

### SUMMARY

One or more example embodiment provides a display panel capable of improved a transparency.

One or more example embodiment provides a method of manufacturing a display panel capable of improved a transparency.

According to example embodiments, a display panel may include an organic light emitting diode, a first film disposed on the organic light emitting diode and a second film including a fluoro polymer and disposed on the first film.

In an example embodiment, the display panel may further include a polarization film disposed between the organic light emitting diode and the first film.

In an example embodiment, the display panel may further include a touch screen panel disposed between the polarization film and the first film.

In an example embodiment, the first film may include polyimide, polystyrene, polyethylene terephthalate, polyethylenenaphthalate or polyethersulfone.

In an example embodiment, the fluoro polymer may include copolymer of tetrafluoroethylene and 2,2-bistrifluoromethyl-4,5-difluoro-1,3-dioxole, ethylene tetrafluoroethylene, fluorinated ethylene propylene, perfluoroalkoxy or polytetrafluoroethylene.

In an example embodiment, the organic light emitting diode may include a thin film transistor disposed on a base substrate, a first electrode on the thin film transistor, an organic light emitting layer disposed on the first electrode and including a hole injection layer, a hole transfer layer, a light emitting layer, an electron transfer layer and an electron injection layer and a second electrode on the organic light emitting layer.

According to another example embodiment, a method of manufacturing a display panel is provided. An organic light emitting diode may be formed. A first film may be formed on the organic light emitting diode. A second film including a fluoro polymer may be formed on the first film.

In an example embodiment, a polarization film may further provided on the organic light emitting diode.

In an example embodiment, a touch screen panel may further provided on the polarization film.

In an example embodiment, the first film may include polyimide, polystyrene, polyethylene terephthalate, polyethylenenaphthalate or polyethersulfone.

In an example embodiment, the fluoro polymer may include copolymer of tetrafluoroethylene and 2,2-bistrifluoromethyl-4,5-difluoro-1,3-dioxole, ethylene tetrafluoroethylene, fluorinated ethylene propylene, perfluoroalkoxy or polytetrafluoroethylene.

In an example embodiment, a mixture of the fluoro polymer and an organic solvent may be sprayed on the first film to form the second film.

In an example embodiment, the organic solvent may include methanol, ethanol, 1-propanol, 2-propanol, 1-butanol, 2-butanol, 2-methyl-1-butanol, 1-pentanol, cyclohexanol, benzene, toluene, xylene, mesitylene, tetrahydrofuran, dioxane, methyl isobutyl ketone, trichloroethylene, bromobenzene or chlorobenzene.

In an example embodiment, the fluoro polymer may be sprayed by a process such as a dispensing, a screen printing, a spin coating, a slit coating, a bar coating or a nozzle spraying to form the second film.

According to another example embodiment, a method of forming the organic light emitting diode is provided. A thin film transistor may be formed on a base substrate. A first electrode may be formed on the thin film transistor. An organic light emitting layer including a hole injection layer, a hole transfer layer, a light emitting layer, an electron transfer layer and an electron injection layer may be formed on the first electrode. A second electrode may be formed on the organic light emitting layer.

According to the example embodiments, the display panel may include the second film including fluoro polymer. Thus, durability and a transparency of a display panel may be improved.

### BRIEF DESCRIPTION OF THE DRAWINGS

The above and other features and advantages of the present embodiments will become more apparent by describing in detailed example embodiments thereof with reference to the accompanying drawings, in which:

FIG. 1 is a perspective view illustrating a display panel according to an example embodiment;

FIG. 2 is a cross-sectional view illustrating a display panel illustrated in FIG. 1;

FIG. 3 is a cross-sectional view illustrating an organic light emitting diode illustrated in FIG. 1;

FIG. 4 is a cross-sectional view illustrating a touch screen panel illustrated in FIG. 1;

FIGS. 5 to 8 are cross-sectional views illustrating a method of manufacturing a display panel illustrated in FIG. 1;

FIGS. 9 to 13 are cross-sectional views illustrating a method of manufacturing a display panel illustrated in FIG. 1.

### DETAILED DESCRIPTION

Hereinafter, example embodiments will be explained in detail with reference to the accompanying drawings.

In example embodiments, a display panel may be lower substrate of a display device including a sealing substrate, a color filter substrate etc. as an upper substrate. Examples of the display device may include a flat display device such as a liquid crystal display device, an organic light emitting display (OLED), an electrophoresis display device, etc. When the upper substrate of the display device is the color filter substrate, the upper substrate may include a black matrix capable of blocking a leaking light or color filter layers such as a red color filter, a green color filter and a blue color filter, etc., to display color images.

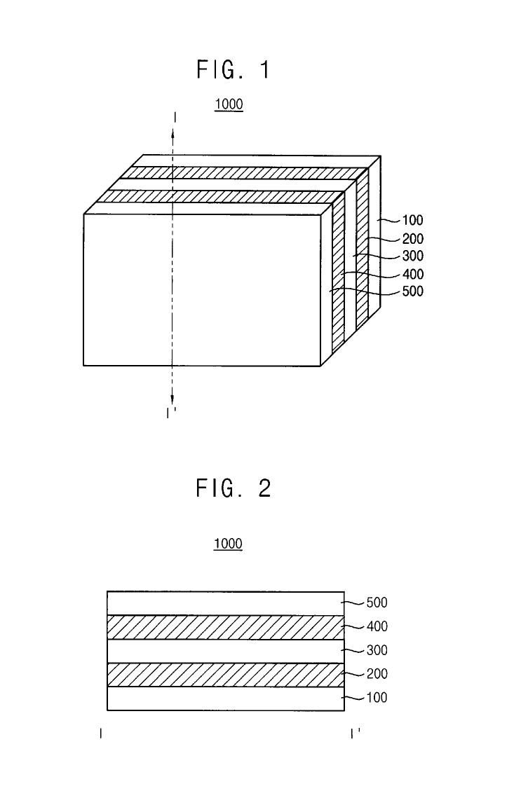

FIG. 1 is a perspective view illustrating a display panel according to an example embodiment. FIG. 2 is a cross-sectional view illustrating a display panel illustrated in FIG. 1.

Referring to FIGS. 1 and 2, a display panel 1000 includes an organic light emitting diode 100, a polarization film 200, a touch screen panel 300, a first film 400 and a second film 500.

Referring to FIG. 2, the polarization film 200 is disposed between the organic light emitting diode 100 and the touch screen panel 300. The polarization film 200 blocks reflection of a light that is externally provided to the organic light emitting diode 100. A linear polarized light parallel with a polarization axis of the polarization film 200 is transmitted and a light not parallel with the polarization axis of the polarization film 200 is absorbed by the polarization film 200. The polarization film 200 may include poly vinyl alcohol.

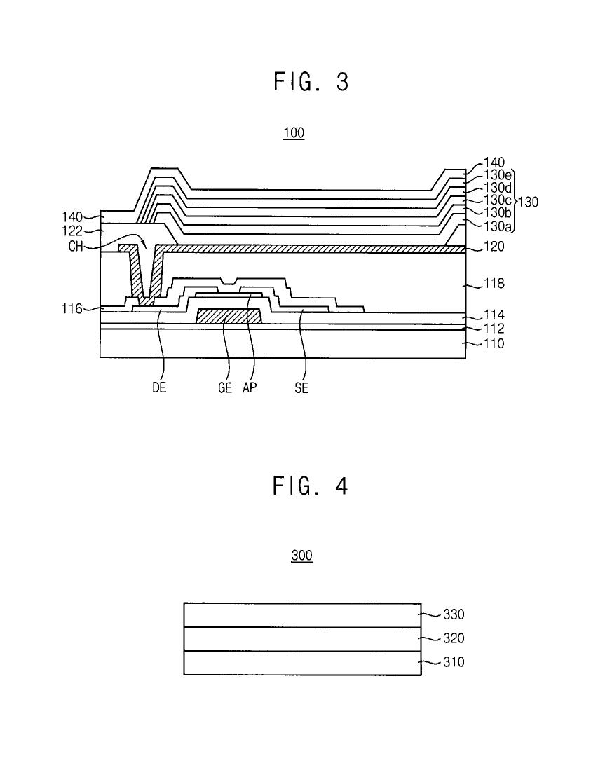

FIG. 3 is a cross-sectional view illustrating an organic light emitting diode illustrated in FIG. 1.

Referring to FIG. 3, the organic light emitting diode 100 includes a base substrate 110, a film transistor TFT, a first electrode 120, a bank layer 122, an organic light emitting layer 130 and a second electrode 140.

The base substrate 110 includes a transparent insulation substrate. Examples of the base substrate 110 may include a glass substrate, a quartz substrate, a transparent resin substrate, etc. Preferably, the base substrate 110 is a flexible substrate such as a transparent resin substrate. The transparent resin substrate may include polyamide resin, acryl resin, polyacrylate resin, polycarbonate resin, polyether resin, polyethylene terephthalate resin, sulfonic acid resin, etc.

The thin film transistor TFT includes a buffer layer 112, a gate electrode GE, a first insulation layer 114, a semiconductor pattern AP, a source electrode SE, a drain electrode DE, a passivation layer 116 and a second insulation layer 118.

The buffer layer 112 protects the thin film transistor from impurities such as alkali ion leaking from the base substrate 110. For example, the buffer layer 112 may include a silicon oxide (SiOx) or a silicon nitride (SiNx).

The gate electrode GE is disposed on the buffer layer 112. For example, the gate electrode GE may include molybdenum, aluminum, chromium, gold, titanium, nickel, neodymium or copper.

The first insulation layer 114 is disposed on the gate electrode GE. For example, the first insulation layer 114 may include a silicon oxide (SiOx) or a silicon nitride (SiNx).

The semiconductor pattern AP is disposed on the first insulation layer 114 and overlaps the gate electrode GE. For example, the semiconductor pattern AP may include amorphous silicon or polycrystalline silicon.

The source electrode SE is spaced apart from the drain electrode DE. The source electrode SE and the drain electrode DE overlap the gate electrode GE. For example, the source electrode SE and the drain electrode DE may include molybdenum, aluminum, chromium, gold, titanium, nickel, neodymium or copper.

The passivation layer 116 entirely covers the source electrode SE and the drain electrode DE. The passivation 116 includes a contact hole CH to expose a portion of the drain electrode DE.

The second insulation layer 118 is disposed on the passivation layer 116. For example, the second insulation layer 118 may include a silicon oxide (SiOx) or a silicon nitride (SiNx).

The first electrode 120 is disposed on the second insulation layer 118. The first electrode 120 may function as an anode or a cathode. The first electrode 120 may be a reflective electrode or a transmission electrode according to light emitting type of the organic light emitting display device. When a first electrode 120 is a transmission electrode, the first electrode may include indium zinc oxide (IZO), indium tin oxide (ITO), gallium zinc oxide (GZO), zinc oxide (ZnOx), gallium oxide (GaOx), tin oxide (TiOx), indium oxide (InOx), etc. When a first electrode 120 is a reflection electrode, the first electrode may include aluminum(Al), silver(Ag), gold(Au), platinum(Pt), chromium(Cr), tungsten(W), molybdenum(Mo), titanium(Ti), palladium(Pd), etc.

When the organic light emitting display device has an active driving type, a switching structure may be disposed between the base substrate 100 and the first electrode 120. For example, the switching structure may include a switching element such as a transistor and a plurality of insulation layers, and may be electrically connected to the first electrode 110.

The bank layer 122 is disposed on the first electrode 120. The bank layer 122 includes an opening portion to expose a portion of the first electrode 120.

The organic light emitting layer 130 is disposed on the opening portion of the bank layer 122. The organic light emitting layer 130 includes a hole injection layer 130a, a hole transfer layer 130b, a light emitting layer 130c, an electron transfer layer 130d and a electron injection layer 130e.

The hole injection layer 130a is disposed on the first electrode 120. The hole injection layer 130a serves to move efficiently positive holes provided from the first electrode 120 to improve electrical characteristics. For example, the hole injection layer 130a may include CuPc(cupper phthalocyanine), PEDOT(poly(3,4)-ethylenedioxythiophene), PANI(polyaniline) or NPD(N,N-dinaphthyl-N,N′-diphenyl benzidine).

The hole transfer layer 130b is disposed on the hole injection layer 130a. For example, the hole transfer layer 130b may include NPD(N,N-dinaphthyl-N,N′-diphenyl benzidine), TPD(N,N′-bis-(3-methylphenyl)-N,N′-bis-(phenyl)-benzidine), s-TAD, MTDATA(4,4′,4″-Tris(N-3-methylphenyl-N-phenyl-amino)-triphenylamine), etc.

The light emitting layer 130c may include a light emitting layer emitting a light such as red, green, blue or white color. The light emitting layer 130c may include a multiple light emitting layer including lamination of the light emitting layers.

The electron transfer layer 130d may improve electrical characteristics. For example, the electron transfer layer 130d may include Alq3(tris(8-hydroxyquinolino)aluminum), PBD, TAZ, Spiro-PBD, BAlq or SAlq.

The electron injection layer 130e serves to move electrons. For example, the electron injection layer 130e may include Alq3(tris(8-hydroxyquinolino)aluminum), PBD, TAZ, spiro-PBD, BAlq or SAlq.

The second electrode 140 is disposed on the organic light emitting layer 130. The second electrode 140 may be may be an anode or a cathode. When the first electrode 120 is an anode, the second electrode 140 is a cathode. When the first electrode 120 is a cathode, the second electrode 140 is an anode. The second electrode 140 may be a reflective electrode or a transmission electrode according to type of the first electrode 120. When a first electrode 120 may be a transmission electrode, a second electrode 140 may be a reflective electrode. The second electrode may include aluminum(Al), silver(Ag), gold(Au), platinum(Pt), chromium(Cr), tungsten(W), molybdenum(Mo), titanium(Ti), palladium(Pd), etc. When a first electrode 120 may be a reflective electrode, a second electrode 140 may be a transmission electrode. The second electrode 140 may include indium zinc oxide (IZO), indium tin oxide (ITO), gallium zinc oxide (GZO), zinc oxide (ZnOx), gallium oxide (GaOx), tin oxide (TiOx), indium oxide (InOx), etc.

FIG. 4 is a cross-sectional view illustrating a touch screen panel illustrated in FIG. 1.

Referring to FIG. 4, the touch screen panel 300 is disposed between the polarization film 200 and the first film 400. The touch screen panel 300 includes a first conductive layer 310, a polymer layer 320 and a second conductive layer 330. The polymer layer 320 is disposed between the first conductive layer 310 and the second conductive layer 330.

The first conductive layer 310 and the second conductive layer 330 are formed by a process such as a face-target sputtering, a thermal evaporatoration, a plasma sputtering or a flash evaporatoration.

When the first conductive layer 310 and the second conductive layer 330 are formed by the face-target sputtering, the first conductive layer 310 and the second conductive layer 330 may include ITO(Indium Tin Oxide) or IZO(Indium Zinc Oxide).

When the first conductive layer 310 and the second conductive layer 330 are formed by the thermal evaportatoration, the first conductive layer 310 and the second conductive layer 330 may include carbon nano tube(CNT).

When the first conductive layer 310 and the second conductive layer 330 are formed by the flash evaporatoration, the first conductive layer 310 and the second conductive layer 330 may include conductive polymer.

In another example embodiment, a connection line and a connection pad, which connect to the first conductive layer 310 and the second conductive layer 330, may further disposed on the base substrate 100.

Referring to FIG. 2, the first film 400 is disposed on the touch screen panel 300. The second film 500 is disposed on the first film 400.

The first film 400 may include polyimide, polystyrene, polyethylene terephthalate, polyethylenenaphthalate or polyethersulfone. These can be used alone or in a combination thereof.

The second film 500 may include a fluoro polymer such as Teflon. For example, the fluoro polymer may include copolymer of tetrafluoroethylene and 2,2-bistrifluoromethyl-4,5-difluoro-1,3-dioxole, ethylene tetrafluoroethylene, fluorinated ethylene propylene, perfluoroalkoxy or polytetrafluoroethylene. These can be used alone or in a combination thereof.

For example, the copolymer of tetrafluoroethylene and 2,2-bistrifluoromethyl-4,5-difluoro-1,3-dioxole is represented by following Chemical Formula 1.

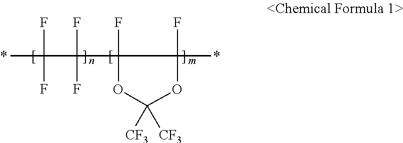

(wherein m and n are natural numbers)

For example, ethylene tetrafluoroethylene is represented by following Chemical Formula 2.

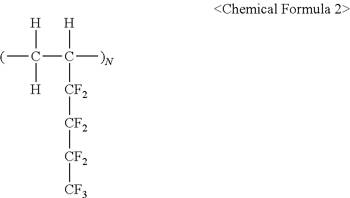

(wherein N is a natural number)

For example, fluorinated ethylene propylene is represented by following Chemical Formula 3.

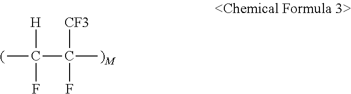

(wherein M is a natural number)

For example, perfluoroalkoxy is represented by following Chemical Formula 4.

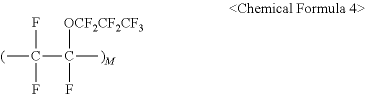

(wherein M is a natural number)

For example, polytetrafluoroethylene is represented by following Chemical Formula 5.

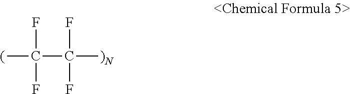

(wherein N is a natural number)

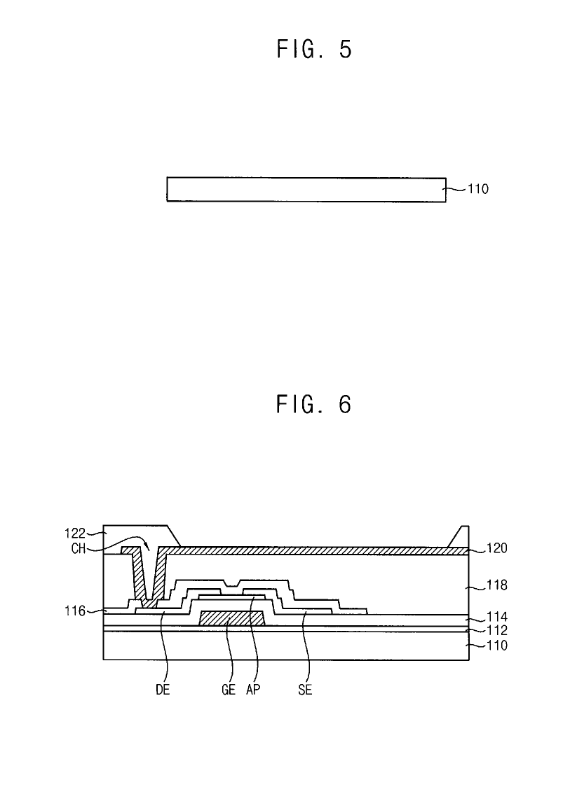

FIGS. 5 to 8 are cross-sectional views illustrating a method of manufacturing a display panel illustrated in FIG. 1.

Referring to FIGS. 5 and 6, an organic light emitting diode 100 is formed. For example, a thin film transistor TFT, a first electrode 120, a bank layer 122, an organic light emitting layer 130 and a second electrode 140 are sequentially formed on a base substrate 110.

The base substrate 110 includes a transparent insulation substrate. Examples of the base substrate 110 may include a glass substrate, a quartz substrate, a transparent resin substrate, etc. Preferably, the base substrate 110 is a flexible substrate such as transparent resin substrate. The transparent resin substrate may include polyamide resin, acryl resin, polyacrylate resin, polycarbonate resin, polyether resin, polyethylene terephthalate resin, sulfonic acid resin, etc.

The thin film transistor TFT is formed on the base substrate 110. A buffer layer 112, a gate electrode GE, a first insulation layer 114, a semiconductor pattern AP, a source electrode SE, a drain electrode DE, a passivation layer 116 and a second insulation layer 118 are sequentially formed. Thus, the thin film transistor TFT is formed.

The buffer layer 112 is formed on the base substrate 110. The buffer layer 112 protects the thin film transistor from impurities such as alkali ion leaking from the base substrate 110. For example, the buffer layer 112 may include a silicon oxide (SiOx) or a silicon nitride (SiNx).

The gate electrode GE is formed on the buffer layer 112. For example, the gate electrode GE may include molybdenum, aluminum, chromium, gold, titanium, nickel, neodymium or copper.

The first insulation layer 114 is formed on the gate electrode GE. For example, the first insulation layer 114 may include a silicon oxide (SiOx) or a silicon nitride (SiNx).

The semiconductor pattern AP is formed on the first insulation layer 114 and overlaps the gate electrode GE. For example, the semiconductor pattern AP may be include amorphous silicon or polycrystalline silicon.

The source electrode SE and the drain electrode DE is formed on a portion of the first insulation layer 114. The source electrode SE is spaced apart from the drain electrode DE. The source electrode SE and the drain electrode DE overlap the gate electrode GE. For example, the source electrode SE and the drain electrode DE may include molybdenum, aluminum, chromium, gold, titanium, nickel, neodymium or copper.

The passivation layer 116 is entirely formed on the source electrode SE and the drain electrode DE. A contact hole CH is formed to expose a portion of the drain electrode DE.

The second insulation layer 118 is formed on the passivation layer 116. For example, the second insulation layer 118 may include a silicon oxide (SiOx) or a silicon nitride (SiNx).

The first electrode 120 is formed on the second insulation layer 118. The first electrode 120 may function as an anode or a cathode. The first electrode 120 may be a reflective electrode or a transmission electrode according to light emitting type of the organic light emitting display device. When a first electrode 120 is a transmission electrode, the first electrode may include indium zinc oxide (IZO), indium tin oxide (ITO), gallium zinc oxide (GZO), zinc oxide (ZnOx), gallium oxide (GaOx), tin oxide (TiOx) or indium oxide (InOx), etc. When a first electrode 120 is a reflection electrode, the first electrode may include aluminum(Al), silver(Ag), gold(Au), platinum(Pt), chromium(Cr), tungsten(W), molybdenum(Mo), titanium(Ti), palladium(Pd), etc.

When the organic light emitting display device has an active driving type, a switching structure may be disposed between the base substrate 100 and the first electrode 120. For example, the switching structure may include a switching element such as a transistor and a plurality of insulation layers, and may be electrically connected to the first electrode 110.

The bank layer 122 is formed on the first electrode 120. An opening portion is formed through the bank layer 122 to expose a portion of the first electrode 120.

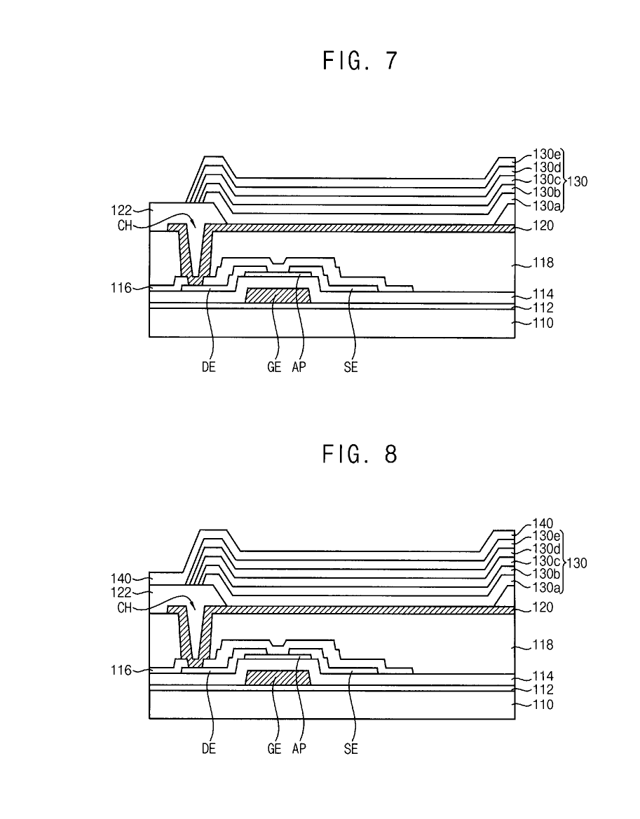

Referring to FIG. 7, the organic light emitting layer 130 is formed on the opening portion of the bank layer 122. A hole injection layer 130a, a hole transfer layer 130b, a light emitting layer 130c, an electron transfer layer 130d and a electron injection layer 130e of the organic light emitting layer 130 are sequentially formed.

The hole injection layer 130a is formed on the first electrode 120. The hole injection layer 130a is entirely formed on the first electrode 120 by a process such as a slit coating, a bar coating or a spin coating.

The hole transfer layer 130b is formed on the hole injection layer 130a. The hole transfer layer 130b is entirely formed on the hole injection layer 130a by a process such as a slit coating, a bar coating or a spin coating.

The light emitting layer 130c is formed on the hole transfer layer 130b. The light emitting layer 130c may be formed on an upper surface of the hole transfer layer 130b by a liquid patterning process. For example, the liquid patterning process may include inkjet printing process, a nozzle printing process, T-jet process or electrostatic coating process.

The light emitting layer 130c may include a light emitting layer emitting a light such as red, green, blue or white color. The light emitting layer 130c may include a multiple light emitting layer including lamination of the light emitting layers.

The electron transfer layer 130d is formed on the light emitting layer 130c. The electron transfer layer 130d may be entirely formed by a process such as a slit coating, a bar coating or a spin coating.

The electron injection layer 130e is formed on the electron transfer layer 130d. The electron injection layer 130e may be entirely formed on the electron transfer layer 130d by a process such as a slit coating, a bar coating or a spin coating.

The hole injection layer 130a, the hole transfer layer 130b, the light emitting layer 130c, the electron transfer layer 130d and the electron injection layer 130e may include materials explained with reference to FIG. 3.

Referring to FIG. 8, the second electrode 140 is formed on the electron injection layer 130e. The second electrode 140 may be an anode or a cathode. When the first electrode 120 is an anode, the second electrode 140 is a cathode. When the first electrode 120 is a cathode, the second electrode 140 is an anode. The second electrode 140 may be a reflective electrode or a transmission electrode according to type of the first electrode 120. When a first electrode 120 may be a transmission electrode, a second electrode 140 may be a reflective electrode. The second electrode may include aluminum(Al), silver(Ag), gold(Au), platinum(Pt), chromium(Cr), tungsten(W), molybdenum(Mo), titanium(Ti) or palladium(Pd), etc. When a first electrode 120 may be a reflective electrode, a second electrode 140 may be a transmission electrode. The second electrode 140 may include indium zinc oxide (IZO), indium tin oxide (ITO), gallium zinc oxide (GZO), zinc oxide (ZnOx), gallium oxide (GaOx), tin oxide (TiOx), indium oxide (InOx), etc. Thus, the organic light emitting diode 100 is formed.

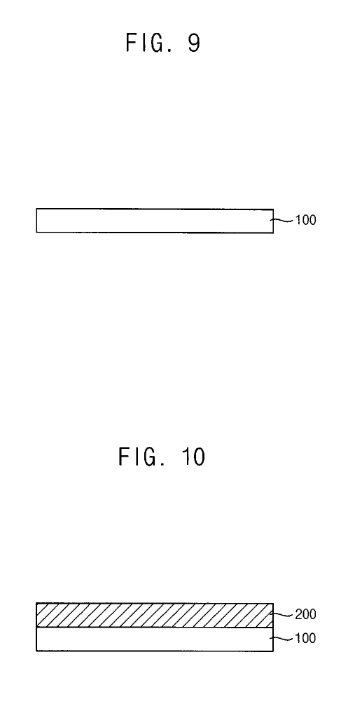

FIGS. 9 to 13 are cross-sectional views illustrating a method of manufacturing a display panel illustrated in FIG. 1.

Referring to FIGS. 9 and 10, the polarization film 200 is formed on the organic light emitting diode 100. The polarization film 200 blocks reflection of a light that is externally provided to the organic light emitting diode 100. A linear polarized light parallel with a polarization axis of the polarization film 200 is transmitted and a light not parallel with the polarization axis of the polarization film 200 is absorbed by the polarization film 200. The polarization film 200 may include poly vinyl alcohol.

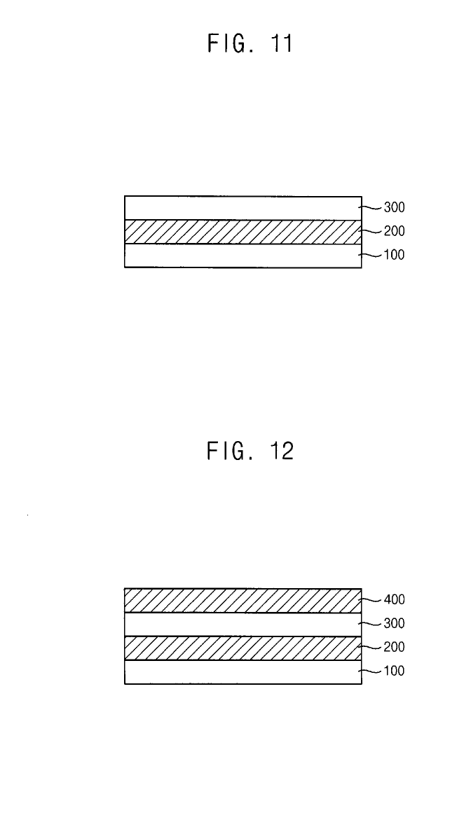

Referring to FIG. 11, the touch screen panel 300 is further provided. The touch screen panel 300 is provided by a process such as a face-target sputtering, a thermal evaporatoration, a plasma sputtering or a flash evaporatoration.

In another example embodiment, when the touch screen panel 300 is provided, a connection line and a connection pad may be further formed on the base substrate 100.

Referring to FIG. 12, the first film 400 is formed on the touch screen panel 300. A material such as polyimide, polystyrene, polyethylene terephthalate, polyethylenenaphthalate or polyethersulfone is sprayed to form the first film 400. These can be used alone or in a combination thereof. The first film 400 may be formed by a process such as a dispensing, a screen printing, a spin coating, a slit coating, a bar coating or a nozzle spraying.

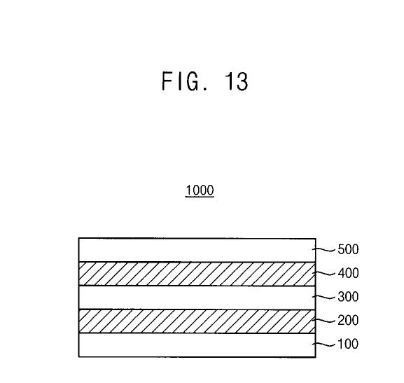

Referring to FIG. 13, the second film 500 is formed on the first film 400.

A mixture of a fluoro polymer and an organic solvent are sprayed on the first film 400 to form the second film 500.

For example, the organic solvent may include alcohol such as methanol, ethanol, 1-propanol, 2-propanol, 1-butanol, 2-butanol, 2-methyl-1-butanol, 1-pentanol, cyclohexanol, aliphatic hydrocarbons such as n-pentane, hexane, n-heptane, isooctane and dodecane, cycloaliphatic hydrocarbons such as cyclopentane and cyclohexane, aromatic hydrocarbons such as benzene, toluene, xylene, mesitylene, cyclic ether such as tetrahydrofuran and dioxane, ketone such as methyl isobutyl ketone, alkane such as trichloroethylene, or halogenated aromatic hydrocarbons such as bromobenzene and chlorobenzene. These can be used alone or in a combination thereof.

For example, the fluoro polymer may include copolymer of tetrafluoroethylene and 2,2-bistrifluoromethyl-4,5-difluoro-1,3-dioxole, ethylene tetrafluoroethylene, fluorinated ethylene propylene, perfluoroalkoxy and polytetrafluoroethylene. These can be used alone or in a combination thereof.

The fluoro polymer is sprayed on the first film 400 by a process such as a dispensing, a screen printing, a spin coating, a slit coating, a bar coating or a nozzle spraying. Thus, the second film 500 is formed.

A flexible display manufactured by a conventional liquid process hardly improves transparency. However, according to the example embodiments, a display panel is manufactured by a liquid process forming a second film including fluoro polymer. Thus, durability and transparency of a display panel may be improved.

The foregoing is illustrative of the embodiments and is not to be construed as limiting thereof. Although a few example embodiments have been described, those skilled in the art will readily appreciate that many modifications are possible in the example embodiments without materially departing from the novel teachings and advantages of the embodiments. Accordingly, all such modifications are intended to be included within the scope of the embodiments as defined in the claims. In the claims, means-plus-function clauses are intended to cover the structures described herein as performing the recited function and not only structural equivalents but also equivalent structures. Therefore, it is to be understood that the foregoing is illustrative of the embodiments and is not to be construed as limited to the specific example embodiments disclosed, and that modifications to the disclosed example embodiments, as well as other example embodiments, are intended to be included within the scope of the appended claims. The embodiments are defined by the following claims, with equivalents of the claims to be included therein.

What is claimed is:

1. A display panel comprising:
an organic light emitting diode;
a first film disposed on the organic light emitting diode; and
a second film comprising a fluoro polymer disposed on the first film.

2. The display panel of claim 1, further comprising a polarization film disposed between the organic light emitting diode and the first film.

3. The display panel of claim 2, further comprising a touch screen panel disposed between the polarization film and the first film.

4. The display panel of claim 1, wherein the first film comprises at least one selected from the group consisting of polyimide, polystyrene, polyethylene terephthalate, polyethylene naphthalate and polyethersulfone.

5. The display panel of claim 1, wherein the fluoro polymer comprises at least one selected from the group consisting of a copolymer of tetrafluoroethylene and 2,2-bistrifluoromethyl-4,5-difluoro-1,3-dioxole, ethylene tetrafluoroethylene, fluorinated ethylene propylene, perfluoroalkoxy and polytetrafluoroethylene.

6. The display panel of claim 1, wherein the organic light emitting diode comprises:
a thin film transistor disposed on a base substrate;
a first electrode on the thin film transistor;
an organic light emitting layer disposed on the first electrode and comprising a hole injection layer, a hole transfer layer, a light emitting layer, an electron transfer layer and an electron injection layer; and
a second electrode on the organic light emitting layer.

7. A method of manufacturing a display panel comprising:
forming an organic light emitting diode;
forming a first film on the organic light emitting diode; and
forming a second film comprising a fluoro polymer on the first film.

8. The method of claim 7, further comprising providing a polarization film on the organic light emitting diode.

9. The method of claim 8, further comprising providing a touch screen panel on the polarization film.

10. The method of claim 7, wherein the first film comprises at least one selected from the group consisting of polyimide, polystyrene, polyethylene terephthalate, polyethylene naphthalate and polyethersulfone.

11. The method of claim 7, wherein the fluoro polymer comprises at least one selected from the group consisting of a copolymer of tetrafluoroethylene and 2,2-bistrifluoromethyl-4,5-difluoro-1,3-dioxole, ethylene tetrafluoroethylene, fluorinated ethylene propylene, perfluoroalkoxy and polytetrafluoroethylene.

12. The method of claim 11, wherein a mixture of the fluoro polymer and an organic solvent is sprayed on the first film to form the second film.

13. The method of claim 12, wherein the organic solvent comprises at least one selected from the group consisting of methanol, ethanol, 1-propanol, 2-propanol, 1-butanol, 2-butanol, 2-methyl-1-butanol, 1-pentanol, cyclohexanol, benzene, toluene, xylene, mesitylene, tetrahydrofuran, dioxane, methyl isobutyl ketone, trichloroethylene, bromobenzene and chlorobenzene.

14. The method of claim 12, wherein the fluoro polymer is sprayed by a dispensing, screen printing, spin coating, slit coating, bar coating or nozzle spraying to form the second film.

15. The method of claim 7, wherein forming the organic light emitting diode comprises:
forming a thin film transistor on a base substrate;
forming a first electrode on the thin film transistor;
forming an organic light emitting layer comprising a hole injection layer, a hole transfer layer, a light emitting layer, an electron transfer layer and an electron injection layer on the first electrode; and
forming a second electrode on the organic light emitting layer.
